(19) United States
(12) Patent Application Publication
(10) Pub. No.: US 2010/0099251 A1
(43) Pub. Date: Apr. 22, 2010

(54) METHOD FOR NITRIDATION PRETREATMENT

(75) Inventors: XINYU FU, Fremont, CA (US); Jick M. Yu, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/256,235

(22) Filed: Oct. 22, 2008

(51) Int. Cl. H01L 21/768

(52) U.S. Cl. 438/653; 257/E21.584

(57) ABSTRACT

In one embodiment, a method for fabricating a damascene structure is provided which includes exposing a dielectric surface on a substrate to a nitrogen plasma to form a nitrided dielectric layer, wherein the dielectric surface contains a plurality of openings therein, depositing a barrier layer on the nitrided dielectric surface, and depositing a seed layer over the barrier layer. In some examples, the nitrogen plasma is formed from nitrogen gas or a mixture of nitrogen gas and hydrogen gas. The nitrogen plasma may be formed in a barrier deposition chamber or by a reactive preclean chamber. In another embodiment, a bulk layer may be deposited to fill the openings after depositing the seed layer. In one example, the bulk layer may contain copper, tungsten, or alloys thereof, and be deposited by an electrochemical plating process.

### BACKGROUND OF THE INVENTION

1. Field of the Invention

Embodiments of the invention generally relate to methods for depositing materials onto a substrate, and more particular, to methods for treating a substrate surface with a nitridation process prior to depositing a metal-containing layer thereon.

2. Description of the Related Art

Copper has become a metal of choice for filling sub-micron, high aspect ratio interconnect features on substrates as circuit densities increase for the next generation of ultra large scale integration. Hence, the line-to-line breakdown voltage and the time dependent dielectric breakdown (TDDB) becomes a significant challenge for reliability.

### SUMMARY OF THE INVENTION

According to an embodiment of the invention, a method for fabricating a conductive damascene structure is provided which includes exposing a dielectric layer containing a plurality of openings and disposed on a substrate to a nitridation process. The surface of the dielectric layer is nitrified to form a thin nitrided layer by plasma nitridation or a rapid thermal nitridation. A barrier layer and a seed layer are sequentially formed on the nitrified layer.

In one embodiment, a method for fabricating a damascene structure is provided which includes exposing a dielectric surface on a substrate to a nitrogen plasma to form a nitrided dielectric layer, wherein the dielectric surface contains a plurality of openings therein, depositing a barrier layer on the nitrided dielectric surface, and depositing a seed layer over the barrier layer. In some examples, the nitrogen plasma is formed from nitrogen gas or a mixture of nitrogen gas and hydrogen gas. The nitrogen plasma may be formed in a barrier deposition chamber or by a remote plasma system. The dielectric surface is usually a silicon-based material, such as silicon oxide, undoped silicate glass, or carbon-doped silicon oxide. The barrier layer may contain tungsten, tungsten nitride, titanium, titanium nitride, tantalum, tantalum nitride, silicides thereof, alloys thereof, or the combinations thereof. The seed layer may contain copper, tungsten, cobalt, ruthenium, alloys thereof, or combinations thereof. In another embodiment, a bulk layer may be deposited to fill the openings after depositing the seed layer. In one example, the bulk layer may contain copper, tungsten, or alloys thereof, and be deposited by an electrochemical plating process.

In another embodiment, a method for fabricating a damascene structure on a substrate is provided which includes producing energized nitrogen ions to react with electron trap sites on a dielectric surface on the substrate, wherein the dielectric surface comprises a plurality of openings therein, and depositing a barrier layer over the dielectric surface. The energized nitrogen ions may be produced by a plasma having a bias power and a wafer bias is within a range from about 10 volts to about 60 volts. The method further provides electrochemically depositing copper over the barrier layer, and removing the copper and the barrier layer higher than the level of the dielectric layer.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1E illustrate a copper metallization process according to an embodiment described herein;

FIG. 2 graphically depicts TDDB behaviors for various samples;

FIG. 3A graphically depicts the breakdown voltage of samples treated by nitrogen plasma and illustrates a cross-sectional diagram of the tested interconnect comb-via structure; and

FIG. 3B graphically depicts the breakdown voltage of samples treated by an annealing process.

### DETAILED DESCRIPTION

Generally, copper metallization comprises sequentially depositing thin layers of a barrier layer and a seed layer onto a dielectric layer having trenches therein, followed by electroplating of copper to a desired thickness. A chemical mechanical polishing (CMP) process after the electroplating step creates a flat surface, on which another dielectric layer is deposited to build up upper interconnections.

It is believed that the CMP interface is one of the most critical factors governing the TDDB behavior. According to embodiments of the invention, methods for nitrifying the surface of the dielectric substrate to form a thin nitrided layer are provided to improve TDDB.

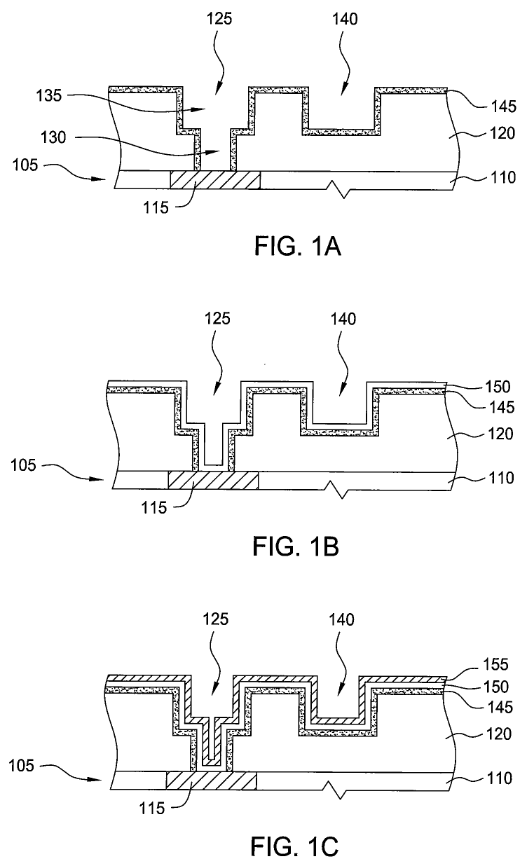

FIGS. 1A-1E illustrate a substrate at different steps while being exposed to a copper metallization process according to an embodiment described herein. In FIG. 1A, a partial cross-sectional diagram of a substrate 105 is shown. The substrate 105 has a first dielectric layer 110 and a conductive line 115 in the first dielectric layer 110. A second dielectric layer 120 is deposited on the substrate 105 and then patterned to form a dual damascene opening 125 and a trench 140. The dual damascene opening 125 typically comprises a via portion 130 and a trench portion 135. Next, the surface of the second dielectric layer 120 is nitrified to form a thin nitrided layer 145, such as a thin nitride layer or a thin nitrogen-doped layer. The thickness of the thin nitrided layer 145 may be within a range from about 1 Å to about 10 Å.

The first dielectric layer 110 and/or the second dielectric layer 120 are a silicon-based material, such as silicon oxide, undoped silicate glass, or carbon-doped silicon oxide, deposited by chemical vapor deposition. In one example, the first dielectric layer 110 and/or the second dielectric layer 120 contains carbon-doped silicon oxide, such as BLACK DIAMOND® dielectric material, available from Applied Materials, Inc. The conductive line 115 may be a metal line, such as a copper line containing metallic copper or a copper alloy.

The nitrified process can be performed by plasma nitridation or rapid thermal nitridation. For plasma nitridation, the surface of the second dielectric layer 120 is exposed to a nitrogen containing plasma to nitrify the surface of the second dielectric layer 120. The source gas of the nitrogen containing plasma comprises nitrogen (N₂) plasma, ammonia (NH₃) plasma, or a nitrogen and ammonia mixture, and the gas flow of the source gas is within a range from about 10 sccm to about 50 sccm. The plasma nitridation can be performed in a barrier deposition chamber or a reactive preclean chamber (e.g., in situ plasma chamber). The related parameters of the plasma nitridation are listed in the Table 1 below, for example.

TABLE 1
Plasma Nitridation

| barrier deposition chamber | | | |
|---|---|---|---|
| (ENCORE ® 2 Ta chamber) | | Reactive preclean chamber | |
| RF power | within a range from | RF power | within a range from |
| | about 1,000 W to | | about 500 W to about |
| | about 1,500 W, for | | 900 W, for example, |
| | example, about | | about 500 W |
| | 1,250 W | | |
| AC bias power | within a range from | Bias power | within a range from |
| | about 100 W to | | about 40 W to about 80 W, |
| | about 250 W, for | | for example, about |
| | example, about 200 W | | 60 W |
| Wafer DC bias | within a range from | — | — |
| | about 10 V to about | | |
| | 60 V, for example, | | |
| | about 50 V | | |
| Gas pressure | within a range from | Gas pressure | within a range from |
| of N₂ | about 0.5 mTorr to | of N₂ | about 0.5 mTorr to |
| | about 2.5 mTorr, for | | about 2.5 mTorr, for |
| | example, about 1.5 mTorr | | example, about 1.5 mTorr |
| Wafer backside | 8 sccm Ar | — | — |
| flow | | | |
| Treatment time | about 10 sec | Treatment time | about 30 sec |

For rapid thermal nitridation, the surface of the second dielectric layer 120 is exposed to a nitrogen-containing gas under a high temperature of about 250° C. to about 400° C. The nitrogen-containing gas may contain a gaseous mixture of nitrogen gas (N₂) and hydrogen gas (H₂), for example. In one embodiment, the hydrogen:nitrogen flow rate ratio is greater than 1, that is, the flow rate of hydrogen gas is greater than the flow rate of nitrogen gas into the chamber. The related parameters of the rapid thermal nitridation are listed in the Table 2 below, for example.

TABLE 2
Rapid Thermal Nitridation
(AKTIV ™ Preclean chamber or Degas chamber)

| | |
|---|---|
| N₂ | 200 sccm |
| H₂ | 400 sccm |
| Pressure | from about 6 Torr to about 8 Torr |
| Temperature | from about 250° C. to about 400° C., for |
| | example, about 300° C. |
| Treatment time | from about 30 sec to about 60 sec |

In FIG. 1B, a barrier layer 150 is deposited over the surface of the thin nitrided layer 145, including the surfaces of the dual damascene opening 125 and the trench 140, and the exposed conductive line 115. The barrier layer 150 is typically deposited using physical vapor deposition (PVD) or by reactive physical vapor deposition. Other deposition processes, such as chemical vapor deposition (CVD) or combination of CVD/PVD, may be used to deposit the barrier layer 150 for modified texture and film properties. The barrier layer 150 limits the diffusion of copper into the second dielectric layer 120 and thereby dramatically increases the reliability of the copper interconnect features. The barrier layer 150 may contain tungsten, tungsten nitride, titanium, titanium nitride, tantalum, tantalum nitride, silicides thereof, alloys thereof, or combinations thereof. In one embodiment, the barrier layer 150 contains two or more layers, for example, titanium and titanium nitride or tantalum and tantalum nitride or tungsten and tungsten nitride.

FIG. 1C depicts a seed layer 155 deposited over the barrier layer 150 using PVD, as described in one embodiment herein. Seed layer 155 may contain copper, tungsten, ruthenium, cobalt, silver, platinum, palladium, alloys thereof, derivatives thereof, or combinations thereof. The seed layer 155 provides good adhesion for a subsequently electroplated copper layer.

FIG. 1D depicts a copper layer 160 electroplated over the copper seed layer 155 to fill the dual damascene opening 125 and the trench 140. FIG. 1E depicts the exposed electroplated copper layer 160 after being planarized, such as by chemical mechanical polishing (CMP). During the planarization process, portions of the copper layer 160, the copper seed layer 155, the nitrided layer 145, and barrier layer 150 are removed to leave a fully planar surface with the dual damascene structure 165 and the connection line 170.

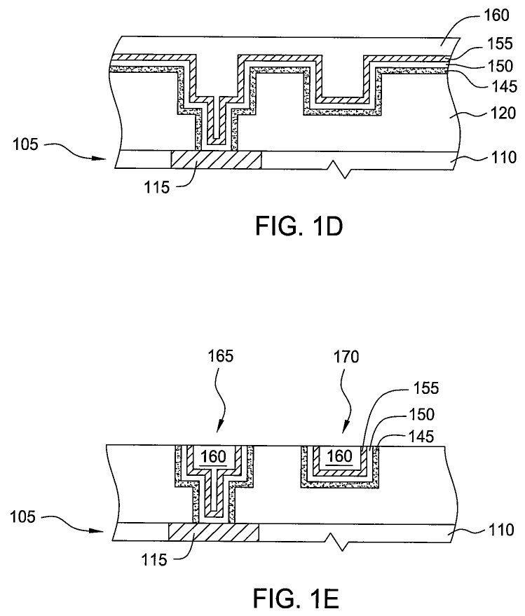

FIG. 2 shows TDDB behaviors for various samples. The horizontal axis of FIG. 2 represents the electric field strength (mV/cm), and the vertical axis of FIG. 2 represents line-to-line breakdown time, T_{bd} (sec). The dielectric layer contains carbon-doped silicon oxide. In FIG. 2, the line-to-line breakdown times of Samples A-D at an electric field of 0.4 MV/cm are also listed in Table 3. It can be seen from FIG. 2 and Table 3 that when Sample D was treated with plasma nitridation, the line-to-line breakdown time was greatly improved over Samples A-C, which were not exposed to a nitrogen plasma treatment.

TABLE 3

| | Sample | | | |
|---|---|---|---|---|
| | A | B | C | D |
| Process | Barrier | Baseline | Barrier Long | Nitrogen |
| Conditions | Deposition | Barrier | Etch | Plasma |
| | with RF | | | |
| Regression | y = 1 × | y = 7 × | y = 5 × 10¹¹ × | y = 1 × 10¹⁵ × |
| Equation | 10¹⁰ × | 10¹⁰ × | e^{-4.215x} | e^{-5.5285x} |
| | e^{-3.2436x} | e^{-3.6597x} | | |
| R² | 0.8759 | 0.9111 | 0.9353 | 0.995 |
| γ-factor | 3.24 | 3.66 | 4.22 | 5.33 |
| (Line Slope) | | | | |
| T_{bd} (sec) | 5E9 | 1E10 | 1E11 | 1E14 |
| at 0.4 MV/cm | | | | |

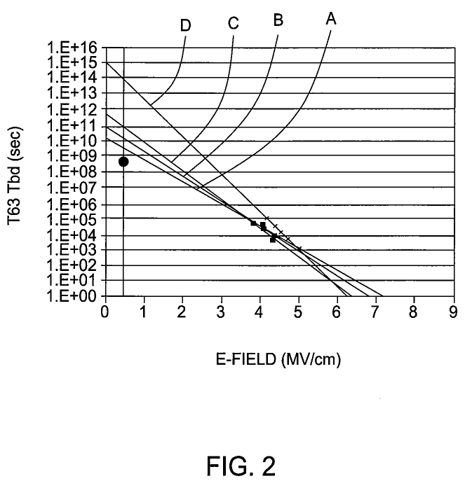

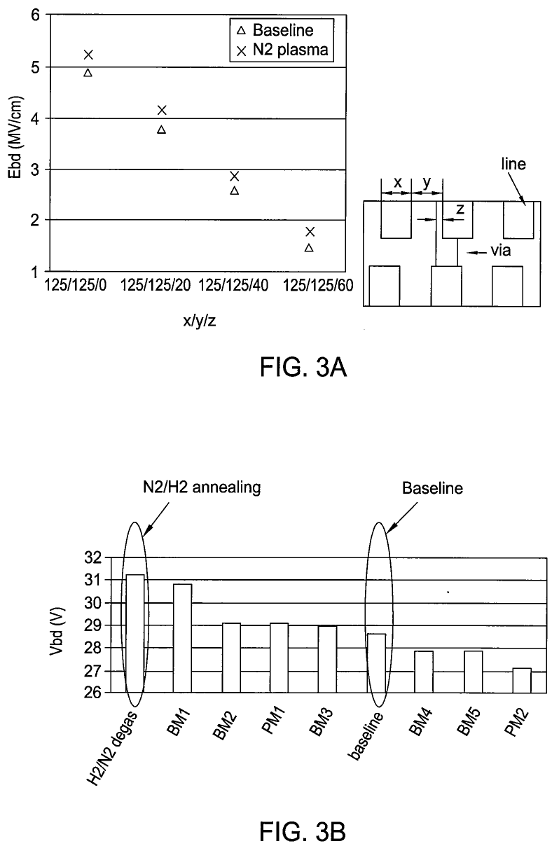

FIG. 3A graphically illustrates the breakdown voltage of samples treated by nitrogen plasma before depositing the barrier layer. FIG. 3A also depicts a cross-sectional view of a tested interconnect structure, such as a comb-via structures. The horizontal axis represents the x/y/z dimensions in a unit of nanometer, and the vertical axis represents the breakdown voltage per unit length in a unit of MV/cm. The dielectric layer used in the samples contained carbon doped silicon oxide. The breakdown voltages of various samples used for the data collected in FIGS. 3A-3B is provided in Table 4 below. FIG. 3B graphically depicts the breakdown voltage of samples treated by an annealing process. The annealing processes at the bottom of the chart in FIG. 3B include H₂/N₂ degas and anneal, BM1 (barrier modulation) for thin DDEF, BM2 for TaN/Ta with preflow, PM1 (preclean modulation) for APC H₂/N₂, BM3 for TaN/Ta, baseline for DDEF, BM4 for sim-D DDEF, BM5 for thick DDEF, and PM2 for RPC. FIGS. 3A-3B and Table 4 provide that the breakdown voltage is also improved by plasma nitridation of the second dielectric layer 120 in FIG. 1A.

TABLE 4

| | Without Pretreatment | Treated by Nitrogen Plasma |
|---|---|---|
| Samples | (mV/cm) | (mV/cm) |
| 125/125/0 (nm) | 4.92 | 5.27 |
| 125/125/20 (nm) | 3.86 | 4.13 |
| 125/125/40 (nm) | 2.64 | 2.95 |
| 125/125/60 (nm) | 1.55 | 1.85 |

The dielectric layer used was undoped silicon glass with a line spacing of about 65 nm. The tested conditions were the same as listed in Table 2. A sample treated by a rapid thermal nitridation process under an atmosphere of a gaseous mixture of nitrogen and hydrogen had a breakdown voltage of 31.3 volts, while a sample not exposed to a pretreatment process had a breakdown voltage of 28.8 volts. Therefore, the breakdown voltage was improved by about 8.7%.

The methods described herein reduce the density of interface electron traps distributed in the second dielectric layer 120. The interface electron traps are produced by incomplete oxide network structure of the dielectric layer. The density of the interface electron traps can be reduced by reacting the interface electron traps with the energized nitrogen ions in the nitrogen plasma of the plasma nitridation or the energized nitrogen atoms in the nitrogen-containing gas of the rapid thermal nitridation to form a silicon nitride like interface having a higher breakdown voltage. Therefore, the TDDB and the current-voltage (I-V) performance are greatly improved by utilizing the methods described herein. Moreover, the extra nitrogen coverage (e.g., the thin nitrided layer) of the dielectric layer may help to create a better tantalum nitride film during deposition.

While the foregoing is directed to embodiments of the present invention, other and further embodiments of the invention may be devised without departing from the basic scope thereof, and the scope thereof is determined by the claims that follow.

1. A method for fabricating a damascene structure, comprising:
exposing a dielectric surface on a substrate to a nitrogen plasma to form a nitrided dielectric layer, wherein the dielectric surface comprises a plurality of openings therein;
depositing a barrier layer on the nitrided dielectric surface; and
depositing a seed layer over the barrier layer.

2. The method of claim 1, wherein a gas source of the nitrogen plasma comprises nitrogen (N₂) or a mixture of nitrogen (N₂) and hydrogen (H₂).

3. The method of claim 2, wherein the nitrogen plasma is formed in a barrier deposition chamber or by a remote plasma system.

4. The method of claim 1, wherein the dielectric surface is a silicon-based material.

5. The method of claim 4, wherein the silicon-based material is silicon oxide, undoped silicate glass, or carbon-doped silicon oxide.

6. The method of claim 1, wherein the barrier layer comprises a material selected from the group consisting of tungsten, tungsten nitride, titanium, titanium nitride, tantalum, tantalum nitride, silicides thereof, and the combinations thereof.

7. The method of claim 1, wherein the seed layer is copper, tungsten, cobalt, ruthenium, alloys thereof, or combinations thereof.

8. The method of claim 1, further comprising electrochemically depositing a metal to fill the openings after depositing the seed layer.

9. The method of claim 8, wherein the metal comprises copper, tungsten, or alloys thereof.

10. A method for fabricating a damascene structure on a substrate, comprising:
forming a silicon nitride layer from an upper surface of a dielectric layer on the substrate, wherein the dielectric layer comprises a plurality of openings therein; and
depositing a metal-containing barrier layer over the silicon nitride layer.

11. The method of claim 10, wherein the silicon nitride layer is formed by plasma nitridation or rapid thermal nitridation.

12. The method of claim 11, wherein the plasma nitridation is performed by a nitrogen plasma in a barrier deposition chamber or a remote plasma clean chamber.

13. The method of claim 12, wherein a nitrogen gas flow in the barrier deposition chamber or the remote plasma clean chamber is within a range from about 10 sccm to about 50 sccm.

14. The method of claim 11, wherein the rapid thermal nitridation is performed under an atmosphere containing nitrogen and hydrogen.

15. The method of claim 11, wherein the rapid thermal nitridation is performed at a temperature of about 250° C. to about 400° C.

16. The method of claim 10, wherein the silicon nitride layer has a thickness within a range from about 1 Å to about 5 Å.

17. The method of claim 10, wherein the barrier layer comprises a material selected from the group consisting of tungsten, tungsten nitride, titanium, titanium nitride, tantalum, tantalum nitride, silicides thereof, and combinations thereof.

18. The method of claim 10, further comprising the following step after depositing the metal-containing barrier layer:
depositing a seed layer over the metal-containing barrier layer; and
electrochemically depositing copper to fill the openings.

19. A method for fabricating a damascene structure on a substrate, comprising:
producing energized nitrogen ions to react with electron trap sites on a dielectric surface on the substrate, wherein the dielectric surface comprises a plurality of openings therein; and
depositing a barrier layer over the dielectric surface.

20. The method of claim 19, wherein the energized nitrogen ions are produced by a plasma having a bias power and a wafer bias is within a range from about 10 volts to about 60 volts.

21. The method of claim 19, further comprising:
electrochemically depositing copper over the barrier layer; and
removing the copper and the barrier layer higher than the level of the dielectric layer.

22. The method of claim 21, wherein the copper is removed by chemical mechanical polishing.
